(19) United States
(12) Patent Application Publication
(10) Pub. No.: US 2008/0157148 A1
(43) Pub. Date: Jul. 3, 2008

(54) Image Sensor and Method for Manufacturing the Same

(76) Inventor: JAE WON HAN, Suwon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/964,304

(22) Filed: Dec. 26, 2007

(30) Foreign Application Priority Data
Dec. 27, 2006 (KR) 10-2006-0135758

(51) Int. Cl. H01L 31/0232; H01L 31/18

(52) U.S. Cl. 257/292; 438/70; 257/E31.127

(57) ABSTRACT

An image sensor and manufacturing process thereof are provided. An image sensor according to an embodiment comprises a first wafer formed with a photodiode cell without a microlens and a second wafer formed with a logic circuit part. The first wafer is stacked on the second wafer such that a connecting electrode can be used to electrically connect the photodiode cell of the first wafer to the logic circuit part of the second wafer.

### CROSS-REFERENCE TO RELATED APPLICATION

The present application claims the benefit under 35 U.S.C. §119 of Korean Patent Application No. 10-2006-0135758, filed Dec. 27, 2006, which is hereby incorporated by reference in its entirety.

### BACKGROUND

In general, an image sensor, which is a semiconductor device converting an optical image into an electrical signal, is typically classified as a charge coupled device (CCD) or a complementary metal oxide silicon (CMOS) image sensor (CIS).

The CIS device according to the related art includes a photodiode region for receiving a light signal and converting it into an electrical signal, and a transistor region for processing the electrical signal.

According to a CMOS image sensor of the related art, a photodiode region and a transistor region are simultaneously manufactured on one wafer.

In this case, because the distance from a lens to the photodiode increases due to a back-end-of-line (BEOL) metal line formed on the transistor region, there is a great loss of the light signal entered into the photodiode region.

Also, according to the related art, because a process is simultaneously performed on the relatively large sized photodiode region and the very small transistor region, a difficulty in a lithography process occurs, which results in many defects occurring, and the photodiode region is attacked in a subsequent process forming a transistor, so that the CIS characteristics would be deteriorated.

Also, according to the related art, the distance from a microlens to a photodiode may be far, which can result in many problems in manufacturing the microlens.

Also, according to the related art, the transistor region is provided in a pixel of a CIS device and affects the fill factor of the device, resulting in a region where incident light cannot be absorbed but, rather, is lost.

### BRIEF SUMMARY

Embodiments of the present invention provide an image sensor and a method for manufacturing the same where a photodiode and a transistor are separately fabricated on different wafers and then connected through a system in a package (SiP).

An embodiment of the present invention provides a method for manufacturing an image sensor manufacturing a specific photodiode on a wafer formed with a photodiode.

An image sensor according to an embodiment of the present invention comprises: a first wafer formed with a photodiode cell without a microlens; a second wafer formed with a logic circuit part; and a connecting electrode electrically connecting the photodiode cell to the logic circuit part.

Also, a method for manufacturing an image sensor according to an embodiment of the present invention comprises: providing a first wafer with a photodiode cell without a microlens; providing a second wafer with a logic circuit part; stacking the first wafer on the second wafer; and electrically connecting the photodiode cell to the logic circuit part.

### BRIEF DESCRIPTION OF THE DRAWINGS

FIGS. 1 to 6 are cross-sectional views of a manufacturing process of a photodiode of a CMOS image sensor according to an embodiment of the present invention.

FIG. 7 is a cross-sectional view of a transistor region of a CMOS image sensor according to an embodiment of the present invention.

FIG. 8 is a cross-sectional view of a CMOS image sensor according to an embodiment of the present invention.

### DETAILED DESCRIPTION

Hereinafter, an image sensor and a method for manufacturing the same according to embodiments of the present invention will be described in detail with reference to the accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more intervening layers may also be present.

In an embodiment, an efficient scheme for manufacturing an image sensor is provided. The scheme involves separately forming a first wafer with a photodiode cell and a second wafer with a logic circuit part, and stacking the first wafer and the second wafer. The photodiode cell formed on the first wafer and the logic circuit part formed on the second wafer can be electrically connected by means of a connecting electrode.

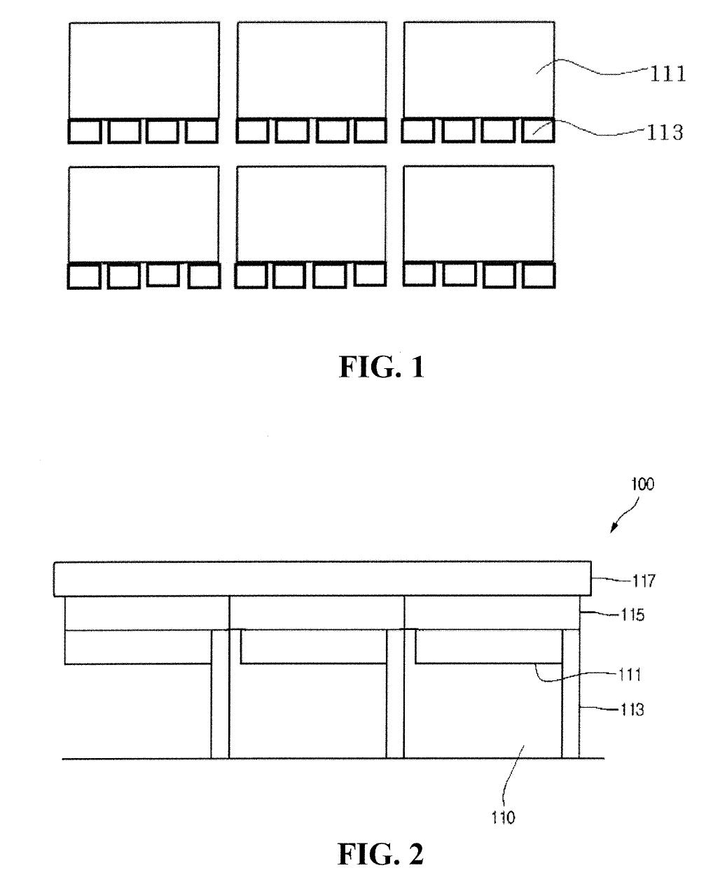

FIG. 1 is a concept view of a wafer formed with a photodiode cell according to an embodiment, and FIG. 2 is a concept view of a cross-section of a wafer 100 formed with a photodiode cell according to an embodiment.

According to a method for manufacturing the image sensor, a first wafer 100 can be manufactured with a photodiode cell 111, a penetrating electrode 113, and a color filter 115.

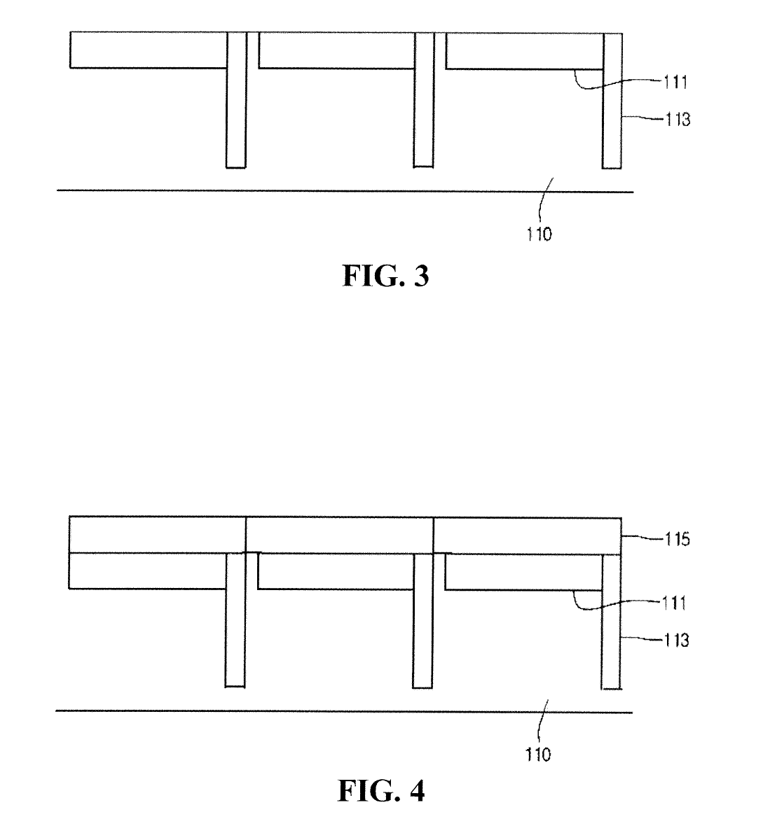

Referring to FIG. 3, a photodiode cell 111 can be formed on an upper region of a semiconductor wafer 110. Then, a penetrating electrode 113 connected to the photodiode cell 111 and penetrating through the semiconductor wafer 110 can be formed.

Accordingly, pixel arrays each configured of only the photodiode 111 for a CIS device can be provided in a design such as shown in FIG. 1.

The pixel arrays can be designed to minimize empty space to reduce the loss of incident light.

The penetrating electrode 113 can be formed by sequentially performing a pattern process, an etching process, and a metal forming process on the semiconductor wafer 110.

The number and placement of the penetrating electrodes 113 can be determined depending on the number of transistors to be used. For example, the pixel may be formed having four electrodes 113 for a 2-transistor type CIS and eight electrodes 113 for a 4-transistor type CIS.

A barrier metal (not shown) can be further formed before the metal of the penetrating electrode 113 is deposited. The barrier metal can be formed of a metal thin layer such as, for example, Ti, TiN, Ti/TiN, Ta, TaN, Ta/TaN, TaN/Ta, Co, Co-compound, Co-nitride, Ni, Ni-compound, Ni-nitride, W, W-compound, or W-nitride.

The barrier metal can be formed using, for example, physical vapor deposition (PVD), sputtering, evaporation, laser ablation, atomic layer deposition (ALD), or chemical vapor deposition (CVD).

In one embodiment, the thickness of the barrier metal can be formed in a range of about 20 to 1000 Å.

Thereafter, the penetrating electrode formed with the barrier metal can be filled with a metal layer.

The penetrating electrode 113 may be formed of, for example, W, Cu, Al, Ag, Au, or a combination thereof. The penetrating electrode 113 can be formed by CVD, PVD, evaporation, electro-chemical plating (ECP), ALD, or laser ablation.

In an embodiment, a trench for forming the penetrating electrode 113 can be etched in the substrate 110 to a depth of about 50 to 500 μm, and the critical dimension (CD) of the penetrating electrode 113 can be about 0.5 to 10 μm.

The metal layer for the penetrating electrode 113 can be deposited until the thickness of the metal layer is about 50 to 900 μm based on a flat plane, in other words, until the metal layer completely fills the penetrating electrode and further rises above the surface thereof.

Thereafter, the metal layer remaining on the substrate is removed and cleaned. As the method for removing the metal layer on the substrate, a process such as a chemical mechanical polish (CMP) or etch back can be used. At this time, the metal layer removing process can be performed until the semiconductor wafer 110 is exposed.

Referring to FIG. 4, a color filter 115 can be formed on the photodiode cell 111.

The manufacturing process of the color filter 115 can include forming red R, green G, and blue B color filters. In one embodiment, the penetrating electrodes 113 are also covered by the color filter 115.

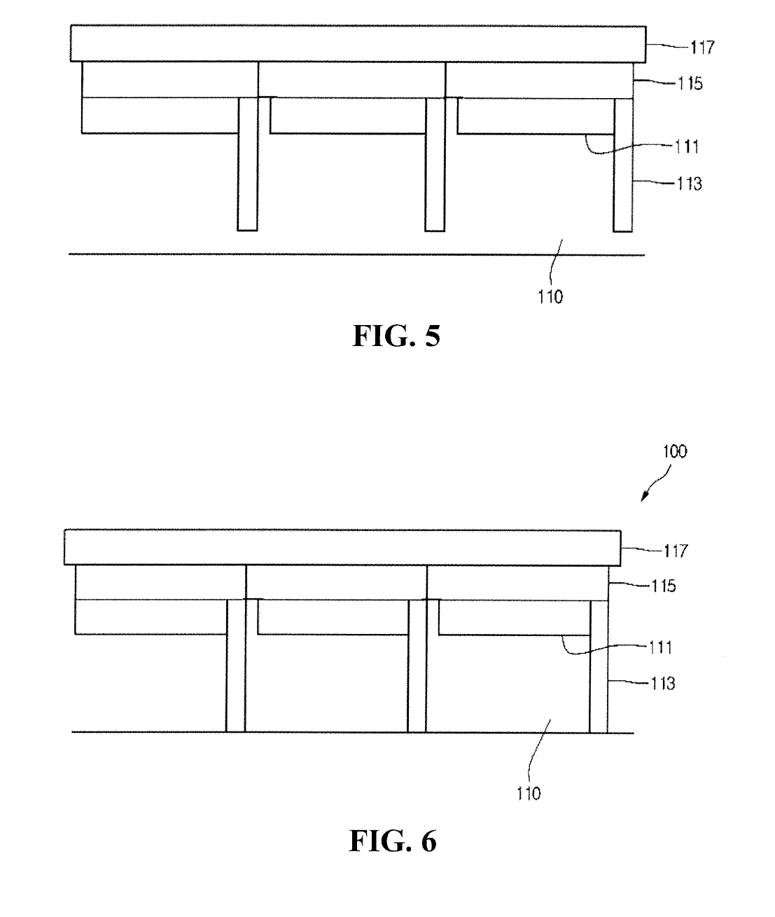

Then, referring to FIG. 5, a protective layer 117 can be formed on the color filter 115.

According to embodiments of the present invention, light is directly incident on the color filter and the photodiode so that a microlens is not needed.

Therefore, a microlens process can be skipped and the protective layer 117 capable of protecting the manufactured photodiode can be deposited.

The protective layer 117 can be formed of, for example, SiO₂, BPSG, TEOS, or SiN using various sources, can be used. The thickness of the protective layer 117 can be about 0.3 to 5 μm. The protective layer 117 can be deposited using an electric furnace, a CVD method, or a PVD method.

Referring to FIG. 6, the penetrating electrode 113 can be exposed at a back surface of the semiconductor wafer 110.

To expose the penetrating electrode 113 at the back side of the semiconductor wafer 110, the semiconductor wafer 110 can be back grinded until the penetrating electrode 113 is exposed at a lower side thereof. The thickness of the semiconductor wafer 110 after being back grinded may be about 50 to 500 μm.

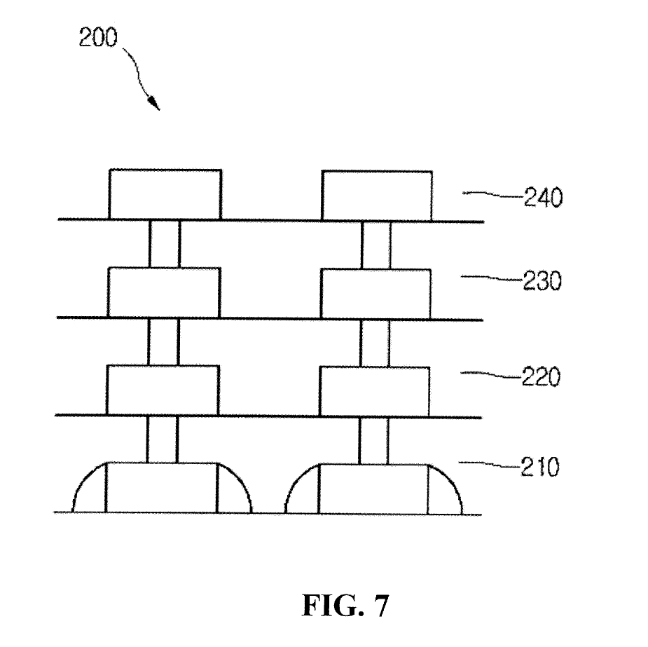

FIG. 7 is a concept view of a wafer 200 formed with a logic circuit part according to a method for manufacturing an image sensor of an embodiment of the present invention.

According to the method for manufacturing the image sensor of an embodiment as shown in FIG. 7, a second wafer 200 can be manufactured comprising a transistor layer 210, a first metal layer 220, a second metal layer 230, and a third metal layer 240.

The transistor layer 210 and the first, second and third metal layers 220, 230, and 240 can form a logic circuit part for signal processing. Herein, the case where the first, second, and third metal layers 220, 230, and 240 are formed is shown by way of example, but the number of the metal layers can be reduced or be further increased depending on the design thereof.

A transistor can formed on the transistor layer 210 in a region corresponding to a photodiode cell 111 region provided in the first wafer 100. The transistor is formed to correspond to the photodiode cell 111 region and it can be formed as one transistor, two transistors, four transistors, or other various configurations for a unit pixel depending on the need thereof.

Since the region of the photodiode cell 111 can be more largely formed as compared to the related art, there is no need to restrict the number of the transistors to be formed. Accordingly, a degree of freedom capable of forming a great number of transistors in order to improve the characteristics of the image sensor is secured, if necessary. Also, there is no need to use a fine circuit process in order to constitute a logic circuit part.

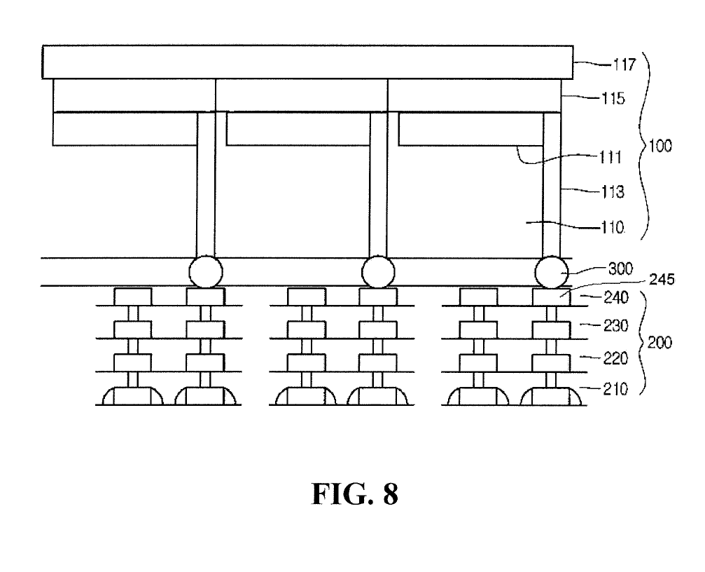

Next, referring to FIG. 8, the first wafer 100 and second wafer 200 can be stacked.

The image sensor according to an embodiment comprises a first wafer 100, a second wafer 200, and a connecting electrode 300.

The connecting electrode 300 connects a photodiode cell 111 formed on the first wafer 100 to a logic circuit part formed on the second wafer 200. The connecting electrode 300 is electrically connected to the photodiode cell 111 through a penetrating electrode 113 formed on the first wafer 100. The connecting electrode 300 is electrically connected to a selected top metal 245 in the third metal layer 240 of the logic circuit part.

With the image sensor according to an embodiment of the present invention, the logic circuit part is not positioned on the photodiode cell 111. In addition, since the photodiode cell 111 can be directly exposed to the light from an external source without additional obstacles, the image sensor manufactured according to an embodiment of the present invention has an advantage that a separate microlens is not required.

With an image sensor and a method for manufacturing the same according to an embodiment as described above, since the image sensor can be manufactured as a system in a package (SiP), the interlayer dielectric layer such as an oxide film, etc. or the metal line layer is not formed on the photodiode so that path of light is short and the loss of light is thus little, making it possible to provide an image sensor of high image quality.

Also, the photodiode process can be performed isolated from the transistors and the transistor manufacturing process.

Also, since there are no interlayer dielectric layer IMD and metal lines on the photodiode region, a microlens is not required to condense incident light to the photodiode so that the manufacturing process can be faster and more economical.

In addition, since a transistor for the logic circuit can be made in a space as wide as the photodiode region, there is no restriction in the number of the transistors so that many transistors can be integrated, having an effect capable of implementing a high quality and a high characteristics image sensor.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a first wafer provided with a photodiode cell without a microlens;
a second wafer provided with a logic circuit part; and
a connecting electrode electrically connecting the photodiode cell to the logic circuit part, wherein the first wafer is stacked on the second wafer.

2. The image sensor according to claim 1, wherein the first wafer comprises:
a photodiode cell formed on a semiconductor substrate of the first wafer;
a penetrating electrode connected to the photodiode cell and penetrating the semiconductor substrate of the first wafer; and
a color filter on the photodiode cell.

3. The image sensor according to claim 2, wherein the first wafer further comprises a protective layer formed over the semiconductor substrate of the first wafer including the color filter.

4. The image sensor according to claim 2, wherein the penetrating electrode comprises W, Cu, Al, Ag, or Au.

5. The image sensor according to claim 2, further comprising a barrier metal between the semiconductor substrate of the first wafer and the penetrating electrode.

6. The image sensor according to claim 5, wherein the barrier metal is formed of Ti, TiN, Ti/TiN, Ta, TaN, Ta/TaN, TaN/Ta, Co, Co-compound, Co-nitride, Ni, Ni-compound, Ni-nitride, W, W-compound, or W-nitride.

7. The image sensor according to claim 1, wherein the second wafer comprises:
a transistor layer for the logic circuit part comprising a transistor formed on a semiconductor substrate of the second wafer; and
a metal layer formed on the transistor layer.

8. The image sensor according to claim 7, wherein the connecting electrode electrically connects the photodiode cell to the logic circuit part using an exposed penetrating electrode of the first wafer and the metal layer of the second wafer.

9. A method for manufacturing an image sensor, comprising:
providing a first wafer provided with a photodiode cell without a microlens;
providing a second wafer provided with a logic circuit part;
stacking the first wafer on the second wafer; and
electrically connecting the photodiode cell to the logic circuit part.

10. The method according to claim 9, wherein the photodiode cell and the logic circuit part are electrically connected through a connecting electrode.

11. The method according to claim 9, wherein providing the first wafer provided with the photodiode cell without the microlens comprises:
forming a photodiode cell on a first semiconductor substrate of the first wafer;
forming a penetrating electrode in the first semiconductor substrate and connected to the photodiode cell; and
forming a color filter on the photodiode cell.

12. The method according to claim 11, wherein providing the first substrate provided with the photodiode cell without the microlens further comprises exposing the penetrating electrode at a lower side of the first wafer after forming the color filter.

13. The method according to claim 12, wherein exposing the penetrating electrode at a lower side of the first wafer comprises performing a chemical mechanical polishing process or an etch back process to the back side of the first wafer.

14. The method according to claim 11, wherein electrically connecting the photodiode cell to the transistor and the capacitor uses a connecting electrode electrically connected to the photodiode cell through the penetrating electrode.

15. The method according to claim 11, wherein the penetrating electrode comprises W, Cu, Al, Ag, and Au.

16. The method according to claim 11, wherein providing the first substrate provided with the photodiode cell without the microlens further comprises forming a barrier metal between the first semiconductor substrate and the penetrating electrode.

17. The method according to claim 16, wherein the barrier metal is formed of Ti, TiN, Ti/TiN, Ta, TaN, Ta/TaN, TaN/Ta, Co, Co-compound, Co-nitride, Ni, Ni-compound, Ni-nitride, W, W-compound, or W-nitride.

18. The method according to claim 16, wherein forming the barrier metal performing a process selected from the group consisting of physical vapor deposition (PVD), sputtering, evaporation, laser ablation, atomic layer deposition (ALD), and chemical vapor deposition (CVD).
